(19) United States
(12) Patent Application Publication
(10) Pub. No.: US 2025/0337418 A1
(43) Pub. Date: Oct. 30, 2025

(54) CHARGE PUMP, PHASE-LOCKED LOOP CIRCUIT AND TRANCEIVER

(71) Applicant: Hangzhou Geo-Chip Technology Co., Ltd., Hangzhou (CN)

(72) Inventor: Chun Geik Tan, San Diego, CA (US)

(73) Assignee: Hangzhou Geo-Chip Technology Co., Ltd., Hangzhou (CN)

(21) Appl. No.: 18/913,839

(22) Filed: Oct. 11, 2024

(30) Foreign Application Priority Data
Apr. 24, 2024 (CN) 202410498144.8

(51) Int. Cl. H03L 7/089; H02M 3/07

(52) U.S. Cl. CPC H03L 7/0895; H02M 3/07

(57) ABSTRACT

The present disclosure provides a charge pump, a phase-locked loop circuit and a transceiver. The charge pump comprises: a first current source circuit comprising a first transistor and a first variable resistor open-loop gain module for causing a voltage at an input terminal of the first transistor to be consistent with a first reference voltage; a second current source circuit comprising a second transistor and a second variable resistor open-loop gain module for causing a voltage at an output terminal of the second transistor to be consistent with a second reference voltage; and a switching circuit coupled to the first and second current source circuits and the loop filter, and configured to control charging of the loop filter in response to an output signal from a phase frequency detector. The charge pump, the phase-locked loop circuit and the transceiver can suppress the flicker noise for the charge pump.

### CROSS-REFERENCE TO RELATED PATENT APPLICATION

This application claims the benefit of and priority to Chinese Patent Application No. 202410498144.8 filed on Apr. 24, 2024, the entire disclosure of which is incorporated by reference herein.

### TECHNICAL FIELD

The present disclosure relates to the field of circuits, and specifically relates to a charge pump, a phase-locked loop circuit, and a transceiver.

### BACKGROUND

This section is intended to provide background or context for the embodiments of the present disclosure as set forth in claims. What is described herein is not admitted as prior art merely by virtue of its inclusion in this section.

In conventional charge pump circuits, charge pump currents are typically produced by active current sources, such as current mirrors or various cascaded current mirror topologies. However, due to the use of active transistors for producing charge pump currents, generation of high flicker noise is inevitable. Moreover, in the scenario of narrow bandwidths, the flicker noise may significantly impact the signal-to-noise ratio of desired signals.

Therefore, it is needed to suppress the flicker noise of the charge pump.

### SUMMARY

In view of the problems existing in the above-mentioned prior art, a charge pump, a phase-locked loop circuit, and a transceiver are proposed in order to solve the above-mentioned problems.

The present disclosure provides the following solutions.

In a first aspect, provided is a charge pump including:
a first current source circuit including a first variable resistor open-loop gain module and a first transistor, the first variable resistor open-loop gain module being connected to the first transistor in such a way that a voltage at an input terminal of the first transistor is consistent with a first reference voltage;
a second current source circuit including a second variable resistor open-loop gain module and a second transistor, the second variable resistor open-loop gain module being connected to the second transistor in such a way that a voltage at an output terminal of the second transistor is consistent with a second reference voltage; and
a switching circuit coupled to the first current source circuit, the second current source circuit and the loop filter and configured to control charging of the loop filter in response to an output signal from a phase frequency detector.

In an embodiment, the first variable resistor open-loop gain module includes a first resistor and a first operational amplifier, where the first resistor is provided between a voltage input terminal and the first transistor, the first transistor is provided between the first resistor and the switching circuit, and the first operational amplifier is connected to the first transistor.

In an embodiment, the second variable resistor open-loop gain module includes a second resistor and a second operational amplifier, where the second resistor is provided between the second transistor and a voltage output terminal, the second transistor is provided between the switching circuit and the second resistor, and the second operational amplifier is connected to the second transistor.

In an embodiment, the switching circuit is configured to, in response to the UP/DOWN signal output by the phase frequency detector, enable the first current source circuit to charge the loop filter, or enable the loop filter to discharge into the second current source circuit. In an embodiment, the first transistor is a PMOS transistor, and the first current source

circuit is a charging current source circuit including a first resistor, a first transistor and a first operational amplifier, where the PMOS transistor has a source connected to the voltage input terminal through the first resistor, and a drain connected to the switching circuit; and the first operational amplifier has a non-inverting input terminal configured to receive the first reference voltage, an inverting input terminal connected to the source of the PMOS transistor, and an output terminal connected to a gate of the PMOS transistor.

In an embodiment, the second transistor is a NMOS transistor, and the second current source circuit is a discharging current source circuit including a second resistor, a second transistor and a second operational amplifier, where the second transistor has a source grounded through the second resistor, and a drain connected to the switching circuit; and the second operational amplifier has a non-inverting input terminal configured to receive the second reference voltage, an inverting input terminal connected to the source of the second transistor, and an output terminal connected to a gate of the second transistor.

In an embodiment, a magnitude of current of the first current source is regulated by adjusting the first reference voltage; and/or a magnitude of current of the second current source is regulated by adjusting the second reference voltage.

In an embodiment, the switching circuit includes a third operational amplifier, a first switch, a second switch, a third switch and a fourth switch, where the third operational amplifier has a non-inverting input terminal connected to the second switch and the fourth switch via a first node, an inverting input terminal, and an output terminal connected to the inverting input terminal and further connected to the first switch and the third switch via a second node; the first switch and the second switch are connected to a drain of the first transistor via a third node; and the third switch and the fourth switch are connected to a drain of the second transistor via a fourth node.

In an embodiment, the first node is connected to an input terminal of the loop filter.

In an embodiment, the second switch is configured to receive the UP signal output by the phase frequency detector, the first switch is configured to receive the inversed UP signal, the fourth switch is configured to receive the DOWN signal output by the phase frequency detector, and the third switch is configured to receive the inversed DOWN signal.

In the second aspect, provided is a phase-locked loop circuit including a phase frequency detector, a loop filter, a voltage-controlled oscillator, a fast-locking control unit, a frequency divider, and a charge pump as in the first aspect.

In the third aspect, provided is a transceiver including a phase-locked loop circuit as in the second aspect.

One of the advantages of the above embodiments lies in that, by providing the first current source circuit and the second current source circuit, the charge pump current can be produced by a resistor, thereby suppressing the flicker noise for the charge pump.

Other advantages of the present disclosure will be explained in more detail with the following description and drawings.

It should be understood that the above description is a summary of the technical solutions of the present disclosure only for the purpose of facilitating a better understanding of the technical means of the present disclosure so that the disclosure can be implemented according to the description in the specification. Specific embodiments of the present disclosure are given below to render the above and other objects, features and advantages of the present disclosure more clear.

### BRIEF DESCRIPTION OF THE DRAWINGS

Through reading the detailed description of the exemplary embodiments below, a person of ordinary skill in the art would understand the advantages and benefits described herein and other advantages and benefits. The drawings are only for the purpose of illustrating exemplary embodiments and are not intended to be limitations to the present disclosure. Moreover, the same reference characters are used throughout the drawings to represent the same components. In the drawings:

FIG. 1 illustrates a conventional charge pump circuit;

FIG. 2 illustrates a schematic diagram of a charge pump circuit according to an embodiment of the present disclosure;

FIG. 3 illustrates a schematic diagram of a charge pump circuit according to another embodiment of the present disclosure;

FIG. 4 illustrates a schematic diagram of a charge pump circuit according to yet another embodiment of the present disclosure;

FIG. 5 is a schematic diagram of a phase-locked loop circuit according to an embodiment of the present disclosure.

In the drawings, the same or corresponding reference characters represent the same or corresponding parts.

### DETAILED DESCRIPTION

The exemplary embodiments of the present disclosure will be described in more detail below with reference to the drawings. Although the exemplary embodiments of the present disclosure are shown in the drawings, it should be understood that the present disclosure can be implemented in various forms and should not be limited by the embodiments described herein. Rather, these embodiments are provided to facilitate more thorough understanding of the present disclosure, so that the scope of the disclosure could be fully conveyed to a person of ordinary skill in the art.

In the description of the embodiments of the present disclosure, it should be understood that terms such as “including” or “having” are intended to indicate the presence of features, numbers, steps, behaviors, components, parts, or combinations thereof disclosed in this specification, and are not intended to exclude the possibility of the presence of one or more other features, numbers, steps, behaviors, components, parts, or combinations thereof.

In the description of the present disclosure, it should be understood that, unless otherwise specified and defined, the terms such as “provide”, “connect” should be comprehended in a broad sense, and may be comprehended as, for example, fixed or detachable connection, or integrated connection; a mechanical or electrical connection; a direct connection or an indirect connection through an intermediate medium; or a communication between interiors of two elements. In addition, the term “couple” is intended to include any direct or indirect electric connection means. The specific meanings of the above terms in the present disclosure may be understood by those skilled in the art according to specific context.

The terms such as “first” and “second” are for descriptive purposes only and are not intended to be construed as indicating or implying a relative importance or implicitly indicating the number of technical features indicated. Hence, features defined by “first” or “second” may explicitly or implicitly include one or more features. In the description of the embodiments of the present disclosure, “a plurality of” means two or more in number, unless otherwise specified.

It should be noted that the charge pump and phase-locked loop disclosed in the present disclosure are more suitable for use in transceivers, especially for wireless communication scenarios such as sub-g (less than 1G) frequency bands. However, the present disclosure is not limited to this, and any phase-locked loop for ultra-low phase noise can be implemented using this structure.

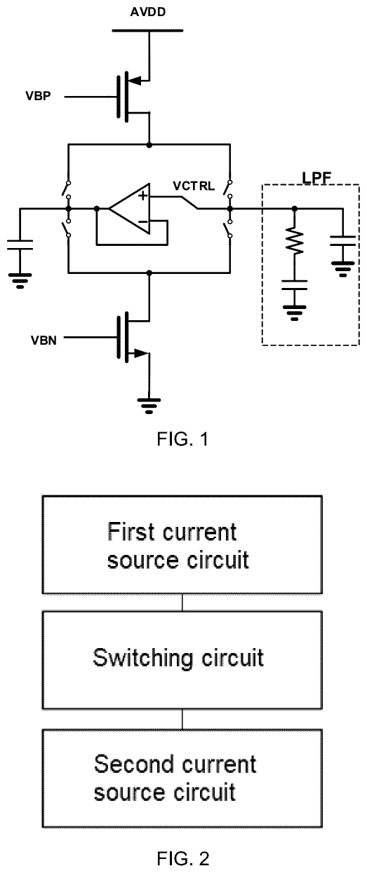

Referring to FIG. 1 illustrating a conventional charge pump circuit, the PMOS transistor has the source connected to the voltage input terminal AVDD, the gate configured to receive the bias voltage VBP, and the drain connected to the loop filter LPF through a switching circuit, thereby ensuring a stable voltage difference between the bias voltage VBP and the input voltage from the voltage input terminal AVDD, that is, enabling generation of a stable drain current as the charging current for the charge pump. Specifically, the drain current generated in the saturation region of a PMOS transistor may be defined by the formula:

$${I}_{ds} = {KC}_{ox} \frac{W}{L} {( {V}_{g} - {V}_{s} )}^{2} ,$$

where I_{ds} denotes the drain current of the PMOS transistor, V_{g} denotes the gate voltage, Vₛ denotes the source voltage, K denotes the coefficient, Cₒₓ denotes the capacitance per unit area of the gate oxide layer, and W/L denotes the width-to-length ratio of the gate oxide layer. Similarly, a stable discharging current for the charge pump can also be achieved through an NMOS transistor and a bias voltage VBN.

In other words, the charge pump current is conventionally produced by an active current device, which may be either a simple current mirror or any cascaded current mirror topology. Since the required charge pump current is generated by a current mirror including active transistors, it contains high flicker noise, thus degrading the low-frequency noise profile of the phase-locked loop (PLL).

In order to at least partially solve the above problems and one or more of other potential problems, the exemplary embodiments of the present disclosure propose a charge pump circuit capable of reducing flicker noise.

The present disclosure will be described in detail below with reference to the accompanying drawings and in combination with the embodiments.

Referring to FIG. 2, embodiments of the present disclosure provide a charge pump, which specifically includes a first current source circuit for controlling a charging operation, a second current source circuit for controlling a discharging operation, and a switching circuit coupled between the first current source circuit and the second current source circuit.

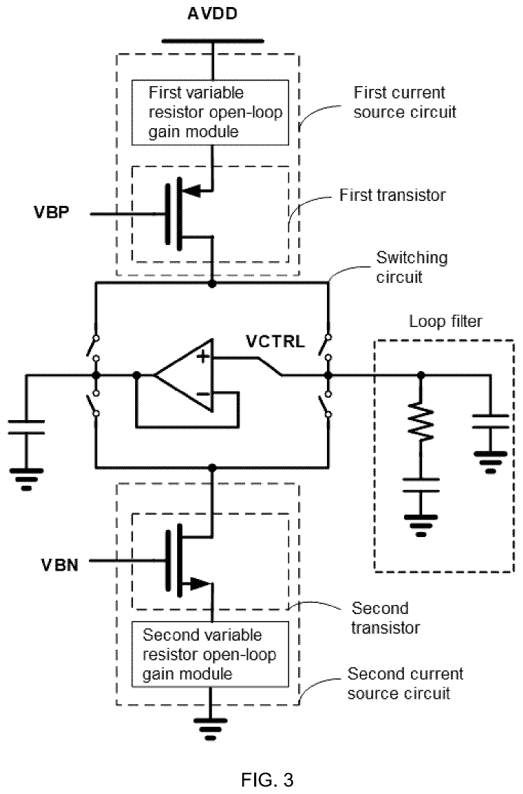

FIG. 3 illustrates a detailed example of the charge pump shown in FIG. 2, from which It can be seen that the charge pump specifically includes:
a first current source circuit including a first variable resistor open-loop gain module and a first transistor, the first variable resistor open-loop gain module being connected to the first transistor in such a way that a voltage at an input terminal of the first transistor is substantially consistent with a first reference voltage;
a second current source circuit including a second variable resistor open-loop gain module and a second transistor, the second variable resistor open-loop gain module being connected to the second transistor in such a way that a voltage at an output terminal of the second transistor is substantially consistent with a second reference voltage; and
a switching circuit coupled to the first current source circuit, the second current source circuit and the loop filter and configured to control charging of the loop filter in response to an output signal from a phase frequency detector.

When the switching circuit enables the first current source circuit to charge the loop filter, the first variable resistor open-loop gain module actually serves as a voltage follower, thus causes the voltage at the input terminal of the first transistor to be substantially consistent with the first reference voltage after running for a period of time, that is, causing a stable voltage at the input terminal of the first transistor, thereby enabling generation of a stable charging current for the charge pump. In this process, the flicker noise of the active device is attenuated in the open-loop gain, thereby minimizing the flicker noise for the phase-locked loop.

When the switching circuit enables the loop filter to discharge into the second current source circuit, the second variable resistor open-loop gain module actually also serves as a voltage follower, thus causes the voltage at the output terminal of the second transistor to be substantially consistent with the second reference voltage after running for a period of time, that is, causing a stable voltage at the output terminal of the second transistor, thereby enabling generation of a stable discharging voltage for the charge pump. In this process, the flicker noise of the active device is attenuated in the open-loop gain, thereby minimizing the flicker noise for the phase-locked loop.

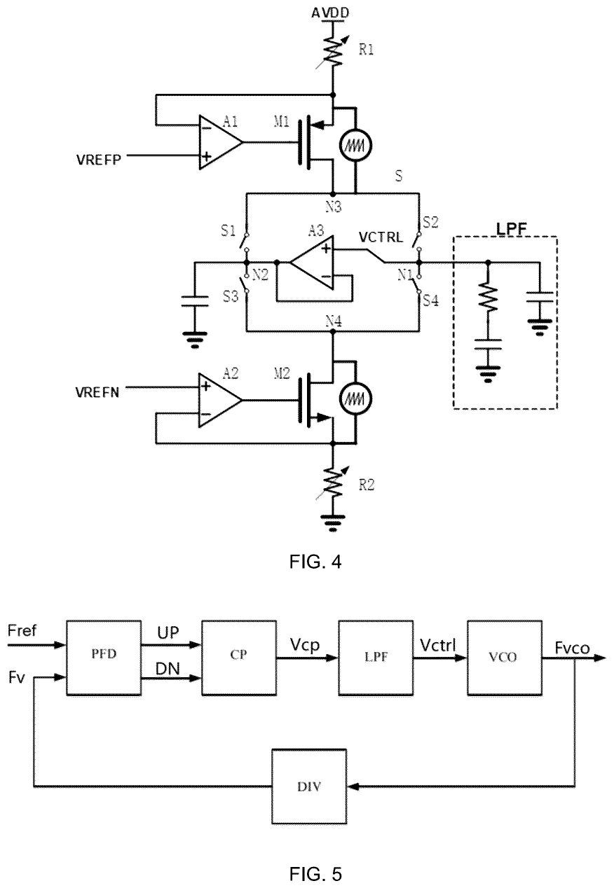

FIG. 4 illustrates a further detailed example of the charge pump shown in FIGS. 2 and 3.

In an embodiment, the first variable resistor open-loop gain module includes a first resistor R1 and a first operational amplifier A1, where the first resistor R1 is provided between the voltage input terminal AVDD and the first transistor M1, the first transistor M1 is provided between the first resistor R1 and the switching circuit S, and the first operational amplifier A1 is connected to the first transistor M1.

In an embodiment, the second variable resistor open-loop gain module includes a second resistor R2 and a second operational amplifier A2, where the second resistor R2 is provided between the second transistor M2 and the voltage output terminal, the second transistor M2 is provided between the switching circuit S and the second resistor R2, and the second operational amplifier A2 is connected to the second transistor M2.

In an embodiment, the switching circuit S is configured to, in response to the UP/DOWN signal output by the phase frequency detector, enable the first current source circuit to charge the loop filter LPF, or enable the loop filter LPF to discharge into the second current source circuit.

It can be understood that either the first variable resistor open-loop gain module or the second variable resistor open-loop gain module may be provided independently in the charge pump, allowing for specific optimization of the charging or discharging process, or both modules may be provided to achieve a more comprehensive advantage in charging and discharging.

The charge pump according to the embodiments of the present disclosure is described in detail below with reference to FIG. 4.

The first current source circuit may serve as a charging current source circuit configured to force a charging current into the loop filter LPF when electrically connected to the loop filter LPF. In an embodiment, the first transistor M1 may be specifically a PMOS transistor, and the charging current source circuit may specifically include the first resistor R1, the first transistor M1 and the first operational amplifier A1, where the first transistor M1 has the source connected to the voltage input terminal AVDD through the first resistor R1, and the drain connected to the switching circuit S; and the first operational amplifier A1 has the non-inverting input terminal configured to receive the first reference voltage VREFP, the inverting input terminal connected to the source of the first transistor M1, and the output terminal connected to the gate of the first transistor M1.

The second current source circuit may serve as a discharging current source circuit configured to force a discharging current from the loop filter LPF when connected to the loop filter LPF. In an embodiment, the discharging current source circuit may specifically include the second resistor R2, the second transistor M2 and the second operational amplifier A2, where the second transistor M2 has the source grounded through the second resistor R2, and the drain connected to the switching circuit S; and the second operational amplifier A2 has the non-inverting input terminal configured to receive the second reference voltage VREFN, the inverting input terminal connected to the source of the second transistor M2, and the output terminal connected to the gate of the second transistor M2.

The switching circuit S may be coupled between the charging current source circuit, the discharging current source circuit and the loop filter LPF, and configured to, in response to the UP/DOWN signal output by the phase frequency detector, enable the charging current source circuit to charge the loop filter LPF, or enable the loop filter LPF to discharge into the discharging current source circuit.

For example, when the switching circuit S enables the charging current source circuit to charge the loop filter LPF, the first operational amplifier A1 actually serves as a voltage follower, thus causes the source voltage of the first transistor M1 to be consistent with the first reference voltage VREFP after running for a period of time, so that the charging current for the charge pump is the ratio of the voltage difference between the voltage input terminal AVDD and the first reference voltage VREFP to the resistance value of the first resistor R1, that is, the charging current for the charge pump is generated by the first resistor R1. In this process, the flicker noise of the active device is attenuated in the open-loop gain, thereby minimizing the flicker noise for the phase-locked loop.

For another example, when the switching circuit enables the loop filter LPF to discharge into the discharging current source circuit, the second operational amplifier A2 actually also serves as a voltage follower, thus causes the source voltage of the second transistor M2 to be consistent with the second reference voltage VREFN after running for a period of time, so that the discharging current for the charge pump is the ratio of the voltage difference between the second reference voltage VREFN and the ground to the resistance value of the second resistor R2, that is, the discharging current for the charge pump is generated by the second resistor R2. In this process, the flicker noise of the active device is attenuated in the open-loop gain, thereby minimizing the flicker noise for the phase-locked loop.

In an embodiment, a magnitude of current of the charging current source may be regulated by adjusting the first reference voltage VREFP; and/or a magnitude of current of the second current source may be regulated by adjusting the second reference voltage VREFN.

Since the charging current for the charge pump is the ratio of the voltage difference between the voltage input terminal AVDD and the first reference voltage VREFP to the resistance value of the first resistor R1 as illustrated above, a jump of the charging current for the charge pump can be achieved by only adjusting the value of the first reference voltage VREFP. Similarly, the current of the discharging current source can also be regulated by adjusting the second reference voltage VREFN, which will not be described in detail here.

In an embodiment, the first resistor R1 and/or the second resistor R2 may be a variable resistor. Thus, the charging and/or discharging current can also be modified by adjusting the respective value of the first resistor and/or the second resistor.

In an embodiment, an overvoltage/overcurrent protection circuit, such as a fuse, is provided between the source and drains of the PMOS transistor and/or the NMOS transistor.

Still referring to FIG. 4, the switching circuit S may include a third operational amplifier A3, a first switch S1, a second switch S2, a third switch S3 and a fourth switch S4, where the non-inverting input terminal of the third operational amplifier A3 is connected to the second switch S2 and the fourth switch S4 via the first node N1; the inverting input terminal of the third operational amplifier A3 is connected to the output terminal that is connected to the first switch S1 and the third switch S3 via the second node N2; the first switch SI and the second switch S2 are connected to the drain of the PMOS transistor M1 via the third node N3; the third switch S3 and the fourth switch S4 are connected to the drain of the NMOS transistor M2 via the fourth node N4.

In an embodiment, the first node NI is connected to the input terminal of the loop filter LPF.

In an embodiment, the second switch S2 receives the UP signal output by the phase frequency detector, the first switch SI receives the inversed UP signal, the fourth switch S4 receives the DOWN signal output by the phase frequency detector, and the third switch S3 receives the inversed DOWN signal.

One of the advantages of the above embodiments lies that, by providing the first current source circuit and the second current source circuit, the charge pump current can be produced by a resistor, thereby suppressing the flicker noise for the charge pump.

The present disclosure further provides a phase-locked loop circuit. Referring to FIG. 5, the phase-locked loop circuit includes a phase frequency detector PFD, a loop filter LPF, a voltage-controlled oscillator VCO, a fast-locking control unit, a frequency divider DIV, and a charge pump CP according to the above embodiments.

The present disclosure further provides a transceiver for receiving and/or transmitting radio frequency signals. The radio frequency transceiver includes at least one phase-locked loop circuit according to the above embodiment. As such, the adverse effects of flicker noise on the transceiver signal can be effectively suppressed.

Although the spirit and principle of the present disclosure have been described with reference to several specific embodiments, it should be understood that the present disclosure is not limited to the disclosed specific embodiments, and the division of various aspects is not intended to mean that the features in these aspects cannot be combined for benefit. Such division is only for the convenience of expression. The present disclosure is intended to cover various modifications and equivalent arrangements included in the spirit and scope of the appended claims.

What is claimed is:

1. A charge pump, comprising:
a first current source circuit comprising a first variable resistor open-loop gain module and a first transistor, the first variable resistor open-loop gain module being connected to the first transistor in such a way that a voltage at an input terminal of the first transistor is consistent with a first reference voltage;
a second current source circuit comprising a second variable resistor open-loop gain module and a second transistor, the second variable resistor open-loop gain module being connected to the second transistor in such a way that a voltage at an output terminal of the second transistor is consistent with a second reference voltage; and
a switching circuit coupled to the first current source circuit, the second current source circuit and a loop filter, and configured to control charging of the loop filter in response to an output signal from a phase frequency detector.

2. The charge pump according to claim 1, wherein the first variable resistor open-loop gain module comprises a first resistor and a first operational amplifier, the first resistor being provided between a voltage input terminal and the first transistor, the first transistor being provided between the first resistor and the switching circuit, and the first operational amplifier being connected to the first transistor.

3. The charge pump according to claim 1, wherein the second variable resistor open-loop gain module comprises a second resistor and a second operational amplifier, the second resistor being provided between the second transistor and a voltage output terminal, the second transistor being provided between the switching circuit and the second resistor, and the second operational amplifier being connected to the second transistor.

4. The charge pump according to claim 1, wherein the switching circuit is configured to, in response to an UP/DOWN signal output by the phase frequency detector, enable the first current source circuit to charge the loop filter, or enable the loop filter to discharge into the second current source circuit.

5. The charge pump according to claim 2, wherein the first transistor is a P-type Metal-Oxide-Semiconductor (PMOS) transistor, and the first current source circuit is a charging current source circuit comprising the first resistor, the first transistor and the first operational amplifier,
wherein the PMOS transistor has a source connected to the voltage input terminal through the first resistor, and a drain connected to the switching circuit; and the first operational amplifier has a non-inverting input terminal configured to receive the first reference voltage, an inverting input terminal connected to the source of the PMOS transistor, and an output terminal connected to a gate of the PMOS transistor.

6. The charge pump according to claim 3, wherein the second transistor is a N-type Metal-Oxide-Semiconductor (NMOS) transistor, and the second current source circuit is a discharging current source circuit comprising the second resistor, the second transistor and the second operational amplifier,
wherein the second transistor has a source grounded through the second resistor, and a drain connected to the switching circuit; and the second operational amplifier has a non-inverting input terminal configured to receive the second reference voltage, an inverting input terminal connected to the source of the second transistor, and an output terminal connected to a gate of the second transistor.

7. The charge pump according to claim 1, wherein a magnitude of current of the first current source is regulated by adjusting the first reference voltage; and/or a magnitude of current of the second current source is regulated by adjusting the second reference voltage.

8. The charge pump according to claim 4, wherein the switching circuit comprises a third operational amplifier, a first switch, a second switch, a third switch and a fourth switch,
wherein the third operational amplifier has a non-inverting input terminal connected to the second switch and the fourth switch via a first node, an inverting input terminal, and an output terminal connected to the inverting input terminal and further connected to the first switch and the third switch via a second node;
the first switch and the second switch are connected to a drain of the first transistor via a third node; and
the third switch and the fourth switch are connected to a drain of the second transistor via a fourth node.

9. The charge pump according to claim 8, wherein the first node is connected to an input terminal of the loop filter.

10. The charge pump according to claim 8, wherein the second switch is configured to receive the UP signal output by the phase frequency detector, the first switch is configured to receive the inversed UP signal, the fourth switch is configured to receive the DOWN signal output by the phase frequency detector, and the third switch is configured to receive the inversed DOWN signal.

11. A phase-locked loop circuit, comprising a phase frequency detector, a loop filter, a voltage-controlled oscillator, a fast-locking control unit, a frequency divider, and a charge pump according to claim 1.

12. The phase-locked loop circuit according to claim 11, wherein the first variable resistor open-loop gain module comprises a first resistor and a first operational amplifier, the first resistor being provided between a voltage input terminal and the first transistor, the first transistor being provided between the first resistor and the switching circuit, and the first operational amplifier being connected to the first transistor.

13. The phase-locked loop circuit according to claim 11, wherein the second variable resistor open-loop gain module comprises a second resistor and a second operational amplifier, the second resistor being provided between the second transistor and a voltage output terminal, the second transistor being provided between the switching circuit and the second resistor, and the second operational amplifier being connected to the second transistor.

14. The phase-locked loop circuit according to claim 11, wherein the switching circuit is configured to, in response to an UP/DOWN signal output by the phase frequency detector, enable the first current source circuit to charge the loop filter, or enable the loop filter to discharge into the second current source circuit.

15. The phase-locked loop circuit according to claim 12, wherein the first transistor is a P-type Metal-Oxide-Semiconductor (PMOS) transistor, and the first current source circuit is a charging current source circuit comprising the first resistor, the first transistor and the first operational amplifier,
wherein the PMOS transistor has a source connected to the voltage input terminal through the first resistor, and a drain connected to the switching circuit; and the first operational amplifier has a non-inverting input terminal configured to receive the first reference voltage, an inverting input terminal connected to the source of the PMOS transistor, and an output terminal connected to a gate of the PMOS transistor.

16. The phase-locked loop circuit according to claim 13, wherein the second transistor is a N-type Metal-Oxide-Semiconductor (NMOS) transistor, and the second current source circuit is a discharging current source circuit comprising the second resistor, the second transistor and the second operational amplifier,
wherein the second transistor has a source grounded through the second resistor, and a drain connected to the switching circuit; and the second operational amplifier has a non-inverting input terminal configured to receive the second reference voltage, an inverting input terminal connected to the source of the second transistor, and an output terminal connected to a gate of the second transistor.

17. The phase-locked loop circuit according to claim 11, wherein a magnitude of current of the first current source is regulated by adjusting the first reference voltage; and/or a magnitude of current of the second current source is regulated by adjusting the second reference voltage.

18. The phase-locked loop circuit according to claim 14, wherein the switching circuit comprises a third operational amplifier, a first switch, a second switch, a third switch and a fourth switch,
wherein the third operational amplifier has a non-inverting input terminal connected to the second switch and the fourth switch via a first node, an inverting input terminal, and an output terminal connected to the inverting input terminal and further connected to the first switch and the third switch via a second node;
the first switch and the second switch are connected to a drain of the first transistor via a third node; and
the third switch and the fourth switch are connected to a drain of the second transistor via a fourth node.

19. The phase-locked loop circuit according to claim 18, wherein the first node is connected to an input terminal of the loop filter.

20. A transceiver, comprising a phase-locked loop circuit according to claim 11.
